(19) United States
(12) Patent Application Publication
(10) Pub. No.: US 2016/0093545 A1
(43) Pub. Date: Mar. 31, 2016

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Cheol-woo LEE, Anyang-si (KR); Kang Soo LEE, Asan-si (KR); Hyeon HWANG, Asan-si (KR)

(73) Assignee: SAMSUNG ELECTRONICS CO., LTD., Suwon-si (KR)

(21) Appl. No.: 14/723,976

(22) Filed: May 28, 2015

(30) Foreign Application Priority Data
Sep. 25, 2014 (KR) 10-2014-0128184

(51) Int. Cl. H01L 23/06; H01L 21/56; H01L 21/52; H01L 23/482

(52) U.S. Cl. CPC H01L 23/06; H01L 23/4827; H01L 21/563; H01L 21/52

(57) ABSTRACT

Provided are a semiconductor package and a method of fabricating the same. The semiconductor package includes: a package substrate; a semiconductor chip mounted on the package substrate and electrically connected to the package substrate; a first protective layer covering the semiconductor chip and having flexibility controlled by at least one of a material type, a thickness, a material composition ratio and viscosity of the first protective layer; and a second protective layer arranged on the first protective layer and having flexibility controlled by at least one of a material type and a thickness of the second protective layer, wherein the first protective layer comprises a first binder resin, a first hardener, and a first hardening catalyst. According to the semiconductor package of the inventive concept, protective layers protecting the semiconductor chip have flexibility, and thus, the semiconductor package may be bent.

### CROSS-REFERENCE TO THE RELATED APPLICATIONS

This application claims priority from Korean Patent Application No. 10-2014-0128184, filed on Sep. 25, 2014, the entire contents of which are hereby incorporated by reference

### BACKGROUND

Apparatuses and methods consistent with exemplary embodiments relate to a semiconductor package and a method of fabricating the same, and more particularly, to a bendable semiconductor package and a method of fabricating the same.

With the recent smartphone market saturation, a market related to a wearable device is rapidly growing. Such a wearable device does not need a high-capacity memory but usually has a bent shape. Thus, there is a need to develop a bendable semiconductor package that may be applied to the wearable device.

### SUMMARY

Exemplary embodiments of the inventive concept provide a bendable semiconductor package.

The exemplary embodiments also provide a method of fabricating the bendable semiconductor package.

The inventive concept is not limited to the embodiments described herein and other aspects of the inventive concept not mentioned herein will be able to be clearly understood by a person skilled in the art from the following descriptions.

In accordance with an exemplary embodiment, there is provided a semiconductor package which may include: a package substrate; a semiconductor chip mounted on the package substrate and electrically connected to the package substrate; a first protective layer covering the semiconductor chip and having flexibility controlled by at least one of a material type, a thickness, a material composition ratio and viscosity of the first protective layer; and a second protective layer arranged on the first protective layer and having flexibility controlled by at least one of a material type and a thickness of the second protective layer, wherein the first protective layer comprises a first binder resin, a first hardener, a first hardening catalyst, and a first filler.

In accordance with another exemplary embodiment, there is provided a semiconductor package which may include: a substrate; a semiconductor chip mounted on the substrate and electrically connected to the substrate; and a protective layer including polyimide and covering the semiconductor chip, wherein the semiconductor ship and the protective layer have a predetermined flexibility determined by controlling a material type, a thickness, a material composition ratio and viscosity.

In accordance with still another exemplary embodiment, there is provided a method of fabricating a semiconductor package which may include: mounting a semiconductor chip on a package substrate; coating a first protective layer having flexibility on a second protective layer having flexibility; placing the first protective layer and the second protective layer on the package substrate so that the semiconductor chip faces the first protective layer; and pressing the semiconductor chip into the first protective layer by using a vacuum lamination process, wherein the first protective layer comprises a first binder resin, a first hardener, and a first hardening catalyst, wherein the flexibility of the first protective layer is controlled by at least one of a material type, a thickness, a material composition ratio and viscosity of the first protective layer, and wherein the flexibility of the second protective layer is controlled by at least one of a material type and a thickness of the second protective layer.

### BRIEF DESCRIPTION OF THE DRAWINGS

The accompanying drawings are included to provide a further understanding of the exemplary embodiments, and are incorporated in and constitute a part of this specification.

In the drawings:

FIG. 1 is a cross sectional view of a semiconductor package according to exemplary embodiments of the inventive concept;

FIGS. 2A, 2B, and 3 to 7 are cross sectional views illustrating a method of fabricating a semiconductor package according to exemplary embodiments of the inventive concept;

FIG. 8 represents an electronic device to which a semiconductor package according to exemplary embodiments of the inventive concept is applied; and

FIG. 9 is an exemplary block diagram of an electronic device to which a semiconductor package according to exemplary embodiments of the inventive concept is applied.

### DETAILED DESCRIPTION OF THE EXEMPLARY EMBODIMENTS

The advantages and features of the inventive concept, and implementation methods thereof will be clarified through the following exemplary embodiments described with reference to the accompanying drawings. The inventive concept may, however, be embodied in different forms and should not be construed as limited to the embodiments set forth herein. Rather, these embodiments are provided to make this disclosure complete and fully convey the scope of the inventive concept to a skilled in the art. Further, the inventive concept is only defined by the scopes of claims. The same reference numerals throughout the disclosure refer to the same components.

The terms used herein are only for explaining the embodiments, not limiting the inventive concept. The terms in a singular form in the disclosure may also include plural forms unless otherwise specified. The terms used herein “comprises” and/or “comprising” do not exclude the presence or addition of one or more additional components, steps, operations and/or elements other than the components, steps, operations and/or elements that are mentioned.

Also, the embodiments in the present disclosure are described with reference to ideal, exemplary cross sectional views and/or plan views of the inventive concept. The thicknesses of layers and regions in the drawings are exaggerated for the effective description of technical content. Thus, the forms of exemplary views may vary depending on manufacturing technologies and/or tolerances. Thus, the embodiments of the inventive concept are not limited to shown specific forms and also include variations in form produced according to manufacturing processes. For example, an etch region shown as a rectangular shape may have a round shape or a shape having a certain curvature. Thus, regions illustrated in the drawings are exemplary, and the shapes of the regions illustrated in the drawings are intended to illustrate the specific shapes of the regions of elements and not to limit the scope of the inventive concept.

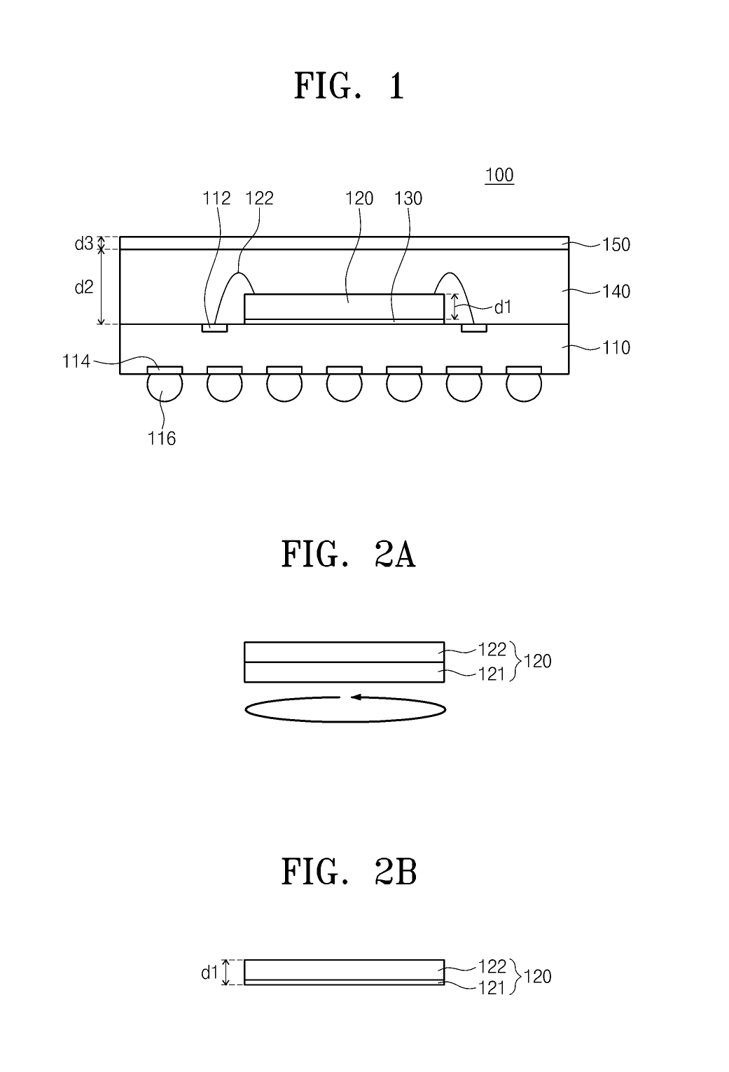

FIG. 1 is a cross sectional view of a semiconductor package according to an embodiment of the inventive concept. In the following, the semiconductor package according to an embodiment of the inventive concept is described with reference to FIG. 1.

Referring to FIG. 1, a semiconductor package 100 may include a package substrate 110, a semiconductor chip 120, an adhesive layer 130, a first protective layer 140 and a second protective layer 150. The first protective layer 140 may include a first binder resin, a first hardener, a first hardening catalyst, and a first filler. The adhesive layer 130 may include a second binder resin, a second hardener, a second hardening catalyst, and a second filler.

The package substrate 110 may have bonding pads 112 and external connection pads 114. The bonding pads 112 may be disposed on a top surface of the package substrate 110 and the external connection pads 114 may be disposed on a bottom surface of the package substrate 110. The bonding pads 112 may be electrically connected to the external connection pads 114 through an interconnection layer (not shown). Solder balls 116 may be disposed on a bottom surface of the external connection pads 114. The package substrate 110 may have flexibility and be a flexible printed circuit board (FPCB), for example.

The semiconductor chip 120 may be mounted on the package substrate 110. The semiconductor chip 120 may be electrically connected to the package substrate 110. As an example, the semiconductor chip 120 may be electrically connected to the package substrate 110 through bonding wires 122 that are electrically connected to the bonding pads 112 of the package substrate 110. Unlike FIG. 1, the semiconductor chip 120 may be electrically connected to the package substrate 110 through a flip chip technique. Also, additional semiconductor chips (not shown) may be mounted on the package substrate 110. As an example, additional semiconductor chips (not shown) may be arranged on the semiconductor chip 120. As another example, additional semiconductor chips (not shown) may be arranged side by side on the same level as the semiconductor chip 120. The semiconductor chip 120 may have flexibility. A thickness d1 of the semiconductor chip 120 is one of factors determining the flexibility of the semiconductor chip 120. The semiconductor chip 120 has greater flexibility as its thickness decreases. Thus, the thickness d1 of the semiconductor chip 120 may be about 1 μm to about 30 μm. The semiconductor chip 120 may be a dynamic random access memory (DRAM), a NAND flash memory, a NOR flash memory, a OneNAND memory, a phase-change RAM (PRAM), a resistive RAM (ReRAM), a magnetic RAM (MRAM), or System on a Chip (SOC), for example.

The adhesive layer 130 may be interposed between the package substrate 110 and the semiconductor chip 120, and may fix the semiconductor chip 120 to the package substrate 110. The adhesive layer 130 may have flexibility. The adhesive layer 130 may include a second binder resin, a second hardener, a second hardening catalyst, and a second filler, as described earlier. The second binder resin may include an acrylic polymer resin and/or epoxy resin. An average molecular weight of the second binder resin may be about 100,000 to about 2,000,000. The second hardener may include an epoxy resin, a phenolic hardening resin, and/or a phenoxy resin. The second hardening catalyst may include a phosphine hardening catalyst, an imidazolium hardening catalyst, and/or an amine hardening catalyst. The second filler may include a silane coupling agent.

The first protective layer 140 may be formed to cover the semiconductor chip 120 and the top surface of the package substrate 110. The first protective layer 140 may have flexibility. The first protective layer 140 may be formed to surround the semiconductor chip 120, and thus, play a role in physically and/or chemically protecting the semiconductor chip 120. The first protective layer 140 may include a first binder resin, a first hardener, a first hardening catalyst, and a first filler, as described earlier. The first binder resin may include an acrylic polymer resin and/or epoxy resin. The average molecular weight of the first binder resin may be less an average molecular weight of the second binder resin. As an example, the average molecular weight of the first binder resin may be about 100 to about 5,000. The first hardener may include an epoxy resin, a phenolic hardening resin, and/or a phenoxy resin. The first hardening catalyst may include a phosphine hardening catalyst, an imidazolium hardening catalyst, and/or an amine hardening catalyst. The first filler may include a silane coupling agent. A composition ratio of the first filler of the first protective layer 140 may be about 0.2 to about 0.3. Thus, viscosity of the first protective layer 140 may be low enough to be capable of covering the semiconductor chip 120.

According to an embodiment, the first binder resin and the second binder resin may include an acrylic polymer resin and an epoxy resin. According to this embodiment, a composition ratio of the acrylic polymer resin of the first binder resin may be smaller than a composition ratio of the acrylic polymer resin of the second binder resin. Since the acrylic polymer resin has a greater molecular weight than the epoxy resin, an average molecular weight of the first binder resin may be less than an average molecular weight of the second binder resin in this embodiment. Thus, viscosity of the first protective layer 140 is lower than that of the adhesive layer 130, and thus, may cover the semiconductor chip 120.

The second protective layer 150 may be formed on the first protective layer 140. The second protective layer 150 may have flexibility and a higher hardness or stiffness than the first protective layer 140. As an example, the second protective layer 150 may include polyimide, polyethylene terephthalate, and/or polyethylene-2,6-naphthalene dicarboxylate. Thus, the second protective layer 150 may play a role in protecting the surface of the semiconductor package 100. Since the second protective layer 150 protects the surface of the semiconductor package 100 unlike the first protective layer 140 surrounding and protecting the semiconductor chip 120, a thickness d3 of the second protective layer 150 may be thinner than the thickness d1 of the first protective layer 140.

As described above, the package substrate 110, the semiconductor chip 120, the adhesive layer 130, the first protective layer 140, and the second protective layer 150 may have flexibility. Thus, since the semiconductor package 100 according to the exemplary embodiments of the inventive concept also has flexibility, it may be bent.

According to an exemplary embodiment, the flexibility or stiffness of the first protective layer 140 may be controllably determined by at least one or two or more of a material type, a thickness, a material composition ratio and viscosity of the first protective layer as described above. Also, the flexibility or stiffness of the second protective layer 150 may be controllably determined by at least one or two or more of a material type and a thickness of the second protective layer as described above. The flexibility or stiffness of the adhesive layer 130 may also be controlled by at least one of a material and a material composition ratio of the adhesive layer 130. In addition, the flexibility or stiffness of the semiconductor package 100 may also be achieved by controlling at least one of a material and a thickness of the semiconductor chip 120, e.g., about 1 μm to about 30 μm, as described earlier. However, according to another exemplary embodiment, the flexibility or stiffness of the first protective layer 140 may be controllably determined by at least one or two or more selected from a material type, a thickness, a material composition ratio and viscosity of the first protective layer as described above. Also, the flexibility or stiffness of the second protective layer 150 may be controllably determined by at least one or two or more selected from a material type and a thickness of the second protective layer as described above. The flexibility or stiffness of the adhesive layer 130 may also be controlled by at least one or two or more selected from a material and a material composition ratio of the adhesive layer 130. In addition, according to another exemplary embodiment, flexibility or stiffness of the semiconductor package 100 may also be achieved by controlling at least one or two or more of a material and a thickness of the semiconductor chip 120. Accordingly, each of the first protective layer 140, the second protective layer 150, the adhesive layer 130 and the semiconductor chip 120 may be configured to have a predetermined flexibility or stiffness which may differ by use of the semiconductor package 100.

FIGS. 2A, 2B, and 3 to 7 are cross sectional views illustrating a method of fabricating a semiconductor package according to exemplary embodiments of the inventive concept. In the following, the method of fabricating the semiconductor package according to the exemplary embodiments of the inventive concept is described with reference to FIGS. 2A, 2B, and 3 to 7.

Referring to FIGS. 2A and 2B, a semiconductor chip 120 may be provided. The semiconductor chip 120 may include a lower wafer 121 and a pattern layer 122 on the lower wafer 121. A portion of the lower part of the lower wafer 121 may be polished and removed. Thus, thicknesses of the lower wafer 121 and the semiconductor chip 120 may decrease. As an example, the thickness d1 of the semiconductor chip 120 may be about 1 μm to about 30 μm. The semiconductor chip 120 may have flexibility, and it may have greater flexibility as the thickness d1 of the semiconductor chip 120 decreases. The pattern layer 122 may be formed by stacking and patterning a plurality of layers on the lower wafer 121. The function of the semiconductor chip 120 may vary depending on the pattern layer 122. For example, the semiconductor chip 120 may be a DRAM, a NAND flash memory, a NOR flash memory, a OneNAND memory, a PRAM, an ReRAM, an MRAM, or System on a Chip (SOC), for example.

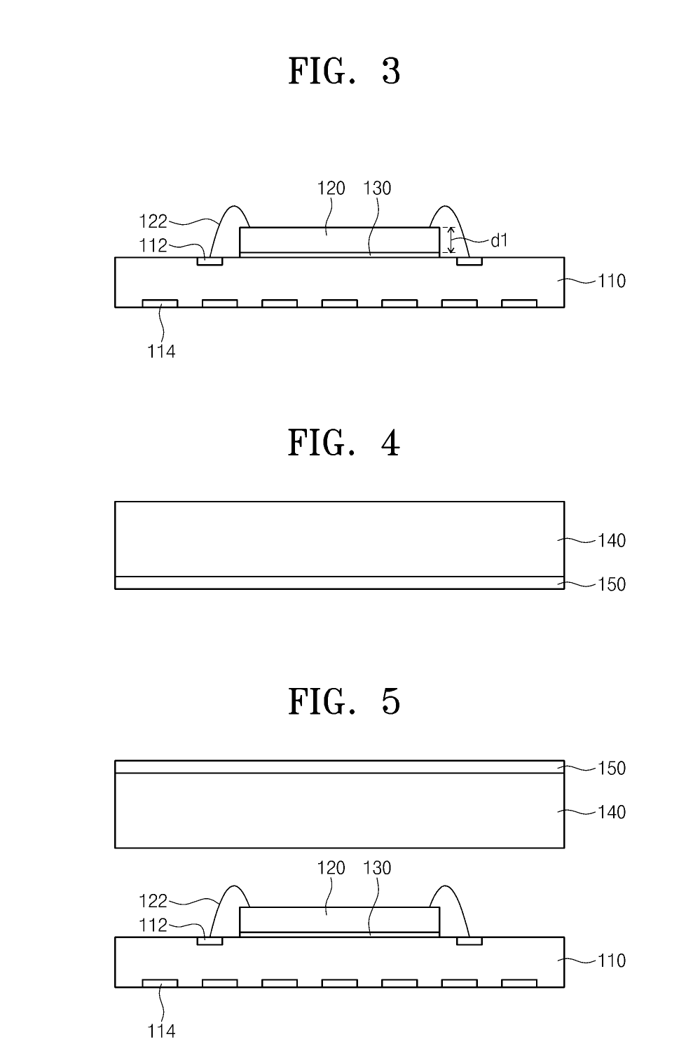

Referring to FIG. 3, the semiconductor chip 120 may be mounted on a package substrate 110. The package substrate 110 may have bonding pads 112 and external connection pads 114. The bonding pads 112 may be disposed on a top surface of the package substrate 110 and the external connection pads 114 may be disposed on a bottom surface of the package substrate 110. The bonding pads 112 may be electrically connected to the external connection pads 114 through an interconnection layer (not shown). The semiconductor chip 120 may be electrically connected to the package substrate 110. As an example, the semiconductor chip 120 may be electrically connected to the package substrate 110 through bonding wires 122 that are electrically connected to the bonding pads 112 of the package substrate 110. Unlike FIG. 1, the semiconductor chip 120 may be electrically connected to the package substrate 110 through a flip chip technique. The package substrate 110 may have flexibility, and be an FPCB, for example.

The semiconductor chip 120 may be fixed to a top surface of the package substrate 110 by the adhesive layer 130. By attaching the adhesive layer 130 on the bottom surface of the semiconductor chip 120 as described with reference to FIGS. 2A and 2B and attaching the semiconductor chip 120 on the top surface of the package substrate 110, it is possible to form the adhesive layer 130 interposed between the package substrate 110 and the semiconductor chip 120 to fix the semiconductor chip 120 to the top of the package substrate 110. The adhesive layer 130 may have flexibility. The adhesive layer 130 may include a second binder resin, a second hardener, a second hardening catalyst, and a second filler. The second binder resin may include an acrylic polymer resin and/or epoxy resin. An average molecular weight of the second binder resin may be about 100,000 to about 2,000,000. The second hardener may include an epoxy resin, a phenolic hardening resin, and/or a phenoxy resin. The second hardening catalyst may include a phosphine hardening catalyst, an imidazolium hardening catalyst, and/or an amine hardening catalyst. The second filler may include a silane coupling agent.

Referring to FIG. 4, a first protective layer 140 may be formed on a second protective layer 150. The first protective layer 140 may have flexibility. The first protective layer 140 may be formed by coating the second protective layer 150 with an adhesive material. The adhesive material may include a first binder resin, a first hardener, a first hardening catalyst, and a first filler. The first binder resin may include an acrylic polymer resin and/or epoxy resin. The average molecular weight of the first binder resin may be less than an average molecular weight of the second binder resin. As an example, the average molecular weight of the first binder resin may be about 100 to about 5,000. The first hardener may include an epoxy resin, a phenolic hardening resin, and/or a phenoxy resin. The first hardening catalyst may include a phosphine hardening catalyst, an imidazolium hardening catalyst, and/or an amine hardening catalyst. The first filler may include a silane coupling agent. A composition ratio of the first filler of the first protective layer 140 may be about 0.2 to about 0.3. Thus, viscosity of the first protective layer 140 may be low enough to be capable of covering the semiconductor chip 120. The second protective layer 150 may have flexibility and a higher hardness of stiffness than the first protective layer 140. As an example, the second protective layer 150 may include polyimide, polyethylene terephthalate, and/or polyethylene-2,6-naphthalene dicarboxylate.

According to an exemplary embodiment, the first binder resin and the second binder resin may include an acrylic polymer resin and an epoxy resin. According to this embodiment, a composition ratio of the acrylic polymer resin of the first binder resin may be smaller than a composition ratio of the acrylic polymer resin of the second binder resin. Since the acrylic polymer resin has a greater molecular weight than the epoxy resin, an average molecular weight of the first binder resin may be less than an average molecular weight of the second binder resin in this embodiment.

Referring to FIG. 5, the protective layers 140 and 150 described with reference to FIG. 4 may be placed on the package substrate 110 so that the semiconductor chip 120 faces the first protective layer 140. The second protective layer 150 may function as a support of the first protective layer 140 in the fabricating process.

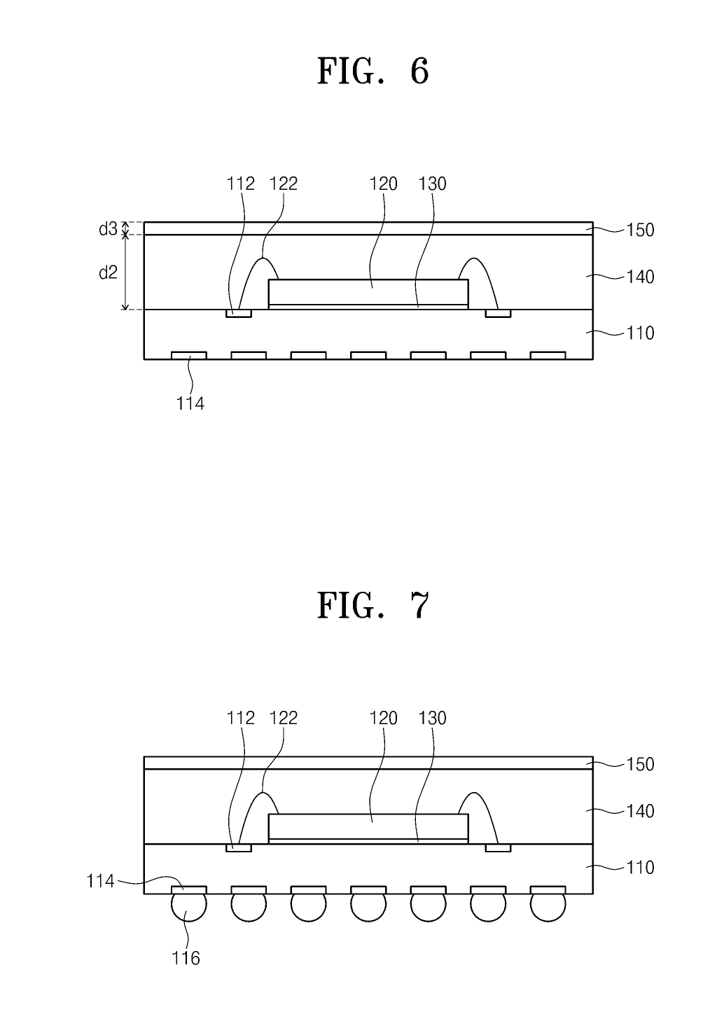

Referring to FIG. 6, the semiconductor chip 120 may be pressed into the first protective layer 140 by using a vacuum lamination process. The vacuum lamination process may be performed at a temperature of about 100° C. to about 150° C. Since the first protective layer 140 includes the first binder resin having an average molecular weight less than that of the second binder resin, the semiconductor chip 120 may have so low viscosity that the semiconductor chip 120 may be pressed into the first protective layer 140 at a temperature of about 100° C. to about 150° C. The semiconductor chip 120 and the bonding wires 122 may be completely covered by the first protective layer 140. Since the first protective layer 140 should cover and protect the semiconductor chip 120, a thickness d2 of the first protective layer 140 may be larger than a thickness d3 of the second protective layer 150.

Referring to FIG. 7, solder balls 116 may be formed on the bottom surface of the external connection pads 114 of the package substrate 110. The package substrate 110 may be electrically connected to an external circuit through the solder balls 116.

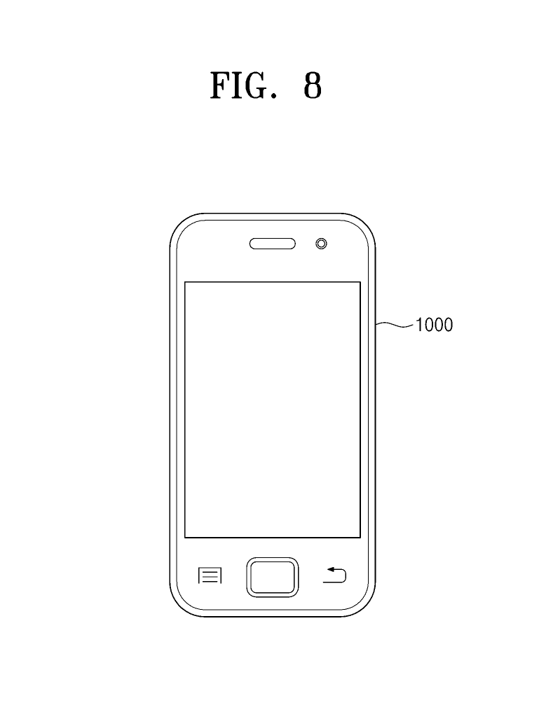

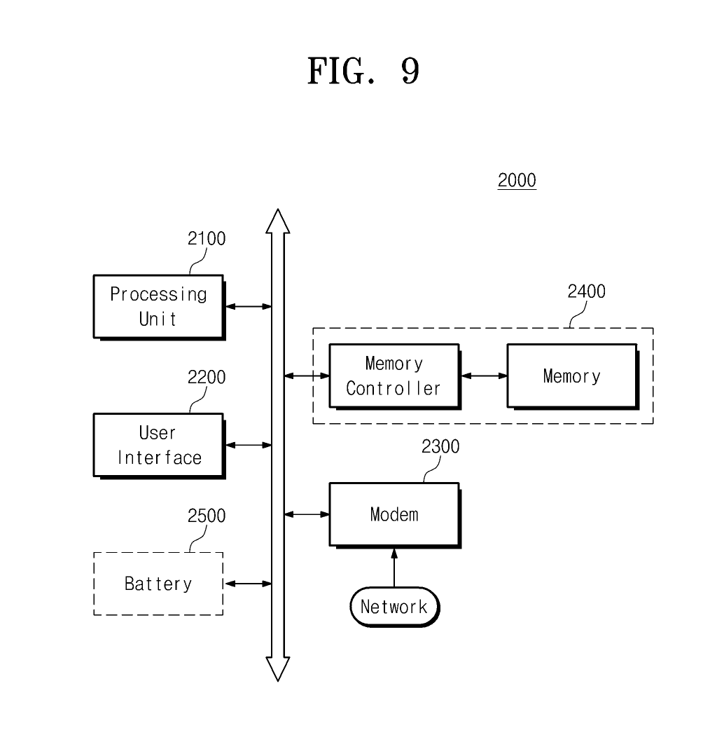

FIG. 8 represents an electronic device to which a semiconductor package according to exemplary embodiments of the inventive concept is applied.

FIG. 8 shows a mobile phone 1000 to which the semiconductor package according to the above embodiments of the inventive concept is applied. As another example, a semiconductor package according to the above embodiments of the inventive concept may be applied to a smartphone, a personal digital assistant (PDA), a portable multimedia player (PMP), a digital multimedia broadcast (DMB) device, a global positioning system (GPS) device, a handled gaming console, a portable computer, a web tablet, a wireless phone, a digital music player, a memory card, a wearable device or all elements that may transmit and/receive information in a wireless environment.

FIG. 9 is an exemplary block diagram of an electronic device to which a semiconductor package according to the above embodiments of the inventive concept is applied.

Referring to FIG. 9, an electronic device 2000 according to the above embodiments of the inventive concept may include a microprocessor 2100, a user interface 2200, a modem 2300, such as a baseband chipset, and a semiconductor package 2400 according to embodiments of the inventive concept.

When the electronic device 2000 according to the above embodiments of the inventive concept is a mobile device, a battery 2500 for supplying the operating voltage of the electronic device may be further provided. Furthermore, it is obvious to a person skilled in the art that the electronic device according to the inventive concept may further include an application chipset, a camera image processor (CIS), etc., though not shown.

According to the semiconductor package of the above embodiments of the inventive concept, protective layers protecting the semiconductor chip have flexibility, and thus, the semiconductor package may be bent.

While exemplary embodiments of the inventive concept are described with reference to the accompanying drawings, a person skilled in the art may understand that the inventive concept may be practiced in other particular forms without changing technical spirits or essential characteristics. Therefore, the exemplary embodiments described above should be understood as illustrative and not limitative in every aspect.

What is claimed is:

1. A semiconductor package comprising:
a package substrate;
a semiconductor chip mounted on the package substrate and electrically connected to the package substrate;
a first protective layer covering the semiconductor chip and having flexibility controlled by at least one of a material type, a thickness, a material composition ratio and viscosity of the first protective layer; and
a second protective layer arranged on the first protective layer and having flexibility controlled by at least one of a material type and a thickness of the second protective layer,
wherein the first protective layer comprises a first binder resin, a first hardener and a first hardening catalyst.

2. The semiconductor package of claim 1, wherein the flexibility of the first protective layer is controlled by a material type, a thickness, a material composition ratio and viscosity of the first protective layer, and wherein the flexibility of the second protective layer is controlled by a material type and a thickness of the second protective layer.

3. The semiconductor package of claim 1, wherein the flexibility of the first protective layer is controlled by at least one selected from a material type, a thickness, a material composition ratio and viscosity of the first protective layer, and
wherein the flexibility of the second protective layer is controlled by at least one selected from a material type and a thickness of the second protective layer.

4. The semiconductor package of claim 1, wherein the first protective layer has a larger thickness than the second protective layer.

5. The semiconductor package of claim 1, wherein the second protective layer has a greater hardness or stiffness than the first protective layer.

6. The semiconductor package of claim 5, wherein the second protective layer comprises polyimide.

7. The semiconductor package of claim 1, wherein a thickness of the semiconductor chip is 1 μm to 30 μm.

8. The semiconductor package of claim 1, further comprising an adhesive layer interposed between the package substrate and the semiconductor chip, the adhesive layer comprising a second binder resin, a second hardener, and a second hardening catalyst, wherein the first binder resin has an average molecular weight less than that of the second binder resin.

9. The semiconductor package of claim 1, further comprising an adhesive layer interposed between the package substrate and the semiconductor chip,
wherein flexibility of the adhesive layer is controlled by at least one of a material and a material composition ratio of the adhesive material.

10. The semiconductor package of claim 8, wherein the first binder resin and the second binder resin comprise an acrylic polymer resin and an epoxy resin, and wherein a composition ratio of the acrylic polymer resin of the first binder is smaller than a composition ratio of the acrylic polymer resin of the second binder resin.

11. The semiconductor package of claim 8, wherein the average molecular weight of the first binder is 100 to 5,000, and the average molecular weight of the second binder resin is 100,000 to 2,000,000.

12. A semiconductor package comprising:
a substrate;
a semiconductor chip mounted on the substrate and electrically connected to the substrate; and
a protective layer comprising polyimide and covering the semiconductor chip,
wherein the semiconductor ship and the protective layer have a predetermined flexibility determined by controlling a material type, a thickness, a material composition ratio and viscosity.

13. The semiconductor package of claim 12, further comprising an adhesive layer interposed between the substrate and the semiconductor chip,
wherein flexibility of the adhesive layer is predetermined by controlling a material and a material composition ratio of the adhesive material.

14. A method of fabricating a semiconductor package, the method comprising:
mounting a semiconductor chip on a package substrate;
coating a first protective layer having flexibility on a second protective layer having flexibility;
placing the first protective layer and the second protective layer on the package substrate so that the semiconductor chip faces the first protective layer; and
pressing the semiconductor chip into the first protective layer by using a vacuum lamination process,
wherein the first protective layer comprises a first binder resin, a first hardener, and a first hardening catalyst,
wherein the flexibility of the first protective layer is controlled by at least one of a material type, a thickness, a material composition ratio and viscosity of the first protective layer, and
wherein the flexibility of the second protective layer is controlled by at least one of a material type and a thickness of the second protective layer.

15. The method of claim 14, wherein the vacuum lamination process is performed at a temperature of 100° C. to 150° C.

16. The method of claim 14, wherein the semiconductor chip comprises a lower wafer, and
wherein the method further comprises grinding the lower wafer of the semiconductor chip to decrease a thickness of the lower wafer, before the mounting of the semiconductor chip.

17. The method of claim 14, wherein the first protective layer has a larger thickness than the second protective layer.

18. The method of claim 14, wherein the second protective layer has a greater hardness or stiffness than the first protective layer.

19. The method of claim 14, wherein the mounting of the semiconductor chip comprises fixing the semiconductor chip on the package substrate through an adhesive layer interposed between the package substrate and the semiconductor chip,
wherein the adhesive layer comprises a second binder resin, a second hardener, and a second hardening catalyst, and
the first binder resin has an average molecular weight less than that of the second binder resin.

20. The method of claim 19, wherein the first binder resin and the second binder resin comprise an acrylic polymer resin and an epoxy resin, and
wherein a composition ratio of the acrylic polymer resin of the first binder is smaller than a composition ratio of the acrylic polymer resin of the second binder resin.
